(19) United States
(12) Patent Application Publication
(10) Pub. No.: US 2020/0243229 A1
(43) Pub. Date: Jul. 30, 2020

(54) Toroidal microinductor comprising a nanocomposite magnetic core

(71) Applicant: National Technology & Engineering Solutions of Sandia, LLC, Albuquerque, NM (US)

(72) Inventors: Eric D. Langlois, Albuquerque, NM (US); Dale L. Huber, Albuquerque, NM (US); John Daniel Watt, Albuquerque, NM (US); Todd Monson, Albuquerque, NM (US)

(21) Appl. No.: 16/552,512

(22) Filed: Aug. 27, 2019

Related U.S. Application Data
(60) Provisional application No. 62/798,795, filed on Jan. 30, 2019.

(51) Int. Cl. H01F 1/00; C08G 59/32; C08K 3/08; C01G 49/08; C23C 18/50; H01F 17/06; H01F 1/047; H01F 38/30; H01L 49/02

(52) U.S. Cl. CPC H01F 1/0018; B82Y 30/00; C08K 3/08; C01G 49/08; C23C 18/50; H01F 1/0054; H01F 17/062; H01F 1/047; H01F 38/30; H01L 28/10; C08K 2003/0856; C08K 2201/011; C08K 2201/01; H01F 2038/305; C01P 2004/64; C08G 59/32

(57) ABSTRACT

A toroidal microinductor comprises a nanocomposite magnetic core employing superparamagnetic nanoparticles covalently cross-linked in an epoxy network. The core material eliminates energy loss mechanisms in existing inductor core materials, providing a path towards realizing low form factor devices. As an example, both a 2 μH output and a 500 nH input microinductors comprising superparamagnetic iron nanoparticles were modeled for a high-performance buck converter. Both modeled inductors had 50 wire turns, less than 1 cm³ form factors, less than 1 ΩAC resistance and quality factors, Q's, of 27 at 1 MHz. In addition, the output microinductor had an average output power of 7 W and power density of 3.9 kW/in³.

### CROSS-REFERENCE TO RELATED APPLICATION

This application claims the benefit of U.S. Provisional Application No. 62/798,795, filed Jan. 30, 2019, which is incorporated herein by reference.

### STATEMENT OF GOVERNMENT INTEREST

This invention was made with Government support under Contract No. DE-NA0003525 awarded by the United States Department of Energy/National Nuclear Security Administration. The Government has certain rights in the invention.

### FIELD OF THE INVENTION

The present invention relates to electrical inductors and, in particular, to a toroidal microinductor comprising a nanocomposite magnetic core.

### BACKGROUND OF THE INVENTION

Switched mode power converters remain popular for battery-powered applications due their higher efficiency as compared to linear regulators. This higher efficiency allows batteries to last longer and circuits to stay cooler. Pushing the ability of power converters to operate at higher frequencies allows for smaller external components, such as transistors, inductors, and capacitors, enabling smaller converter sizes and lowering component costs. There has been a great deal of research lately in wide/ultra-wide band gap SiC, GaN, and AlN transistors for high power electronics. These switches enable great reductions in size and weight due to their material parameters, enabling larger voltages, greater currents, and higher frequencies. Unfortunately, scaling and performance of passive components, such as inductors and capacitors, have not kept pace with the advances made in these high-power transistors. These larger and heavier circuit elements ultimately limit the power densities, operation frequencies, and converter sizes that can be achieved.

However, inductors are not as easy to microfabricate as transistors and are typically added as a separate discrete component. As much as circuit designers would love to eliminate inductors altogether, they perform a vital function as energy storage devices in switched mode power converters. In boost converters, the inductor not only stores energy while the transistor is switched on but also boosts voltage and current to the load, recharging the capacitor in the process, when the transistor is switched off. See S. Keeping, The Inductor's Role in Completing a Power Module-Based Solution [online]. 2011 [retrieved on 17 Apr. 2018], Retrieved from the Internet: <URL: https://www.digikey.com/en/articles/techzone/2011/nov/the-inductors-role-in-completing-a-power-modulebased-solution>. Increasing the switching frequency of the regulator allows the use of a smaller inductor. It turns out that the inductor value is inversely proportional to switching frequency for equal peak-to-peak ripple current. A lower inductor value means fewer loops and/or thinner wire for the coil and a smaller core (area inside the coil), reducing the inductor's volume. Fewer wiring loops means reduced wiring loss, boosting inductor Q's and enabling higher frequency operation. While higher switching frequencies are enabled by these wide band-gap transistors (100 kHz for SiC; 1 MHz or more for nitride-based devices), these improvements cannot be fully taken advantage of currently due to a variety of energy loss mechanisms in these inductors.

To create the next generation of switched mode power converters operating at MHz switching frequencies, smaller form factor, lower core loss, high power density inductors are necessary. Commercially available inductors using current high-performance core materials with traditional copper wire coils are not up to the task for even board level power converter circuit architectures. The problem becomes even more intractable when considering next generation, fully integrated, monolithic, Power Supply on Chips (PSoCs), as shown in FIG. 1. In this situation, it becomes infeasible to use macroscale inductors due to their form factors alone. It also negates the great reductions in size and weight of wide band-gap transistor technology that are making future converter miniaturization possible.

Therefore, there is a need for next generation mesoscale (i.e., mm size) magnetic passive components that go beyond the limits of current technology.

### SUMMARY OF THE INVENTION

The present invention is directed to a toroidal microinductor comprising a nanocomposite magnetic core of superparamagnetic nanoparticles and one or more coil turns surrounding the nanocomposite magnetic core. The superparamagnetic nanoparticles can comprise iron, cobalt, nickel, or alloys or compounds thereof. For example, the superparamagnetic nanoparticles can comprise Fe/FeₓO_{y} core-shell or Fe₃O₄ nanoparticles. The superparamagnetic nanoparticles can be less than 100 nm in diameter, and preferably less than 20 nm in diameter. The superparamagnetic nanoparticles can be suspended in a polymer matrix or covalently cross-linked in an epoxy network.

As an example, toroidal microinductors were simulated by modeling single coil turns and employing periodic boundary conditions for modeling an N-turn microinductor. Designs for both a 2 μH output and a 500 nH input microinductor were created via the model for a high-performance buck converter. Both inductors had 50 wire turns, less than 1 cm³ form factors, less than 1 ΩAC resistance and Q's of 27 at 1 MHz. A modeled average output power of 7 W and power density of 3.9 kW/in³ were obtained with an iron nanocomposite core material.

### BRIEF DESCRIPTION OF THE DRAWINGS

The detailed description will refer to the following drawings, wherein like elements are referred to by like numbers.

FIG. 1 is a schematic illustration of a Power Supply on Chip (PSoC).

FIG. 2A is a plot illustrating hysteresis loss (shaded area inside of curve) in a ferromagnetic material (exaggerated). FIG. 2B is a B vs. H plot of the nanoscale-enabled composite core material showing zero hysteresis.

FIG. 3A is an illustration of Eddy current loss in a bulk and laminated core.

FIG. 3B is an illustration showing that the nanocomposite matrix cannot support an opposing B-field due to electrical isolation of the particles. See Chetvorno, Laminated core eddy currents [online]. 2015 [retrieved on 17 Apr. 2018]. Retrieved from the Internet: <URL: https://commons.wikimedia.org/wiki/File:Laminated_core_eddy_currents.svg>.

FIG. 4A is a schematic illustration of a toriodal microinductor. FIG. 4B is a computer rendering of a single turn rectangular copper coil geometry generated by parametric equations. FIG. 4C is a computer rendering of a single turn core segment.

FIG. 5 is an MH curve for 1^{st} generation superparamagnetic iron nanocomposite material used in the FE model.

FIG. 6 is a rendering of the mesh used for the 2 μH microinductor model. Tetrahedral elements are used for the core, wires, and air volume while swept quadrihedral elements are used for the Infinite Element domains.

FIG. 7A is a plot of magnetic flux density normal for the 2 μH microinductor. FIG. 7B is a plot of magnetic flux density normal for the 500 nH microinductor.

FIG. 8A is a plot of measured inductance data vs. modeled inductance values for image of MnZn ferrite toroidal core, Ferroxcube TC5.8/3.1/1/5-3B7.

FIG. 8B is an image of MnZn ferrite toroidal core. FIG. 8C is a plot of magnetic flux density normal for MnZn ferrite toroidal core.

FIG. 9A is a schematic illustration of the bottom wiring layer of a microinductor. FIG. 9B is a schematic illustration of the middle core layer, comprised of high-aspect-ratio metal vias and a superparamagnetic iron or iron oxide nanocomposite core. FIG. 9C is a schematic illustration of the top wiring layer.

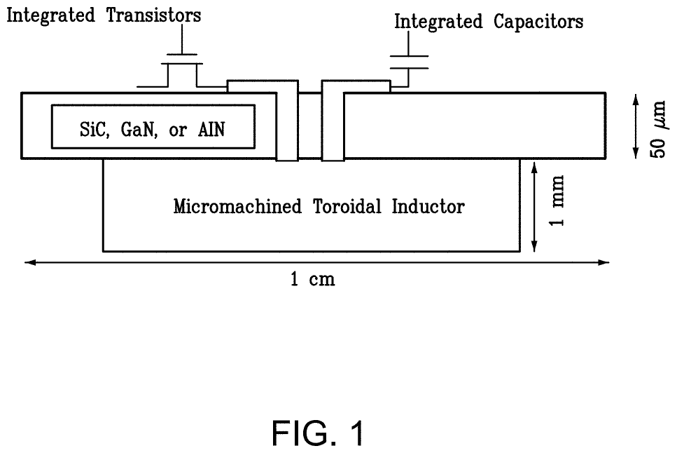

### DETAILED DESCRIPTION OF THE INVENTION

Magnetic core problems that plague most inductors that use existing ferrite, amorphous, or nanocrystalline core materials include high hysteresis and eddy current loss. The toroidal microinductor of the present invention uses a novel nanocomposite magnetic core that employs superparamagnetic nanoparticles as the magnetic fraction. See John Watt et al., J. Mater. Res. 33(15), 2156 (2018); and U.S. application Ser. No. 15/899,043, filed Feb. 19, 2018, both of which are incorporated herein by reference. Superparamagnetic nanoparticles, by definition, possess no hysteresis and are too small to support eddy currents, thereby removing two of the major sources of loss. Generally, the superparamagnetic nanoparticles can comprise iron, cobalt, nickel, or alloys or compounds thereof. For example, the nanocomposite can be formed by first synthesizing gram-scale quantities of Fe/FeₓO_{y} core-shell nanoparticles that can be used as the magnetic fraction. For example, the superparamagnetic nanoparticles can comprise magnetite (Fe₃O₄) which is low-cost, non-toxic and possesses the highest room temperature magnetic saturation of any metal oxide. Superparamagnetic magnetite nanoparticles have been synthesized with an extremely narrow size distribution (10-20 nm). See E. C. Vreeland et al., Chem. Mater. 27, 6059 (2015). Nanocomposites can typically be formed by the organization of sub-100-nm nanoparticles within a polymeric matrix. However, suspension of the nanoparticles in a polymer matrix can sometimes lead to high organic fractions and phase separation; both of which reduce the performance of the resulting material. Therefore, to maximize the nanoparticle loading in the novel nanocomposite, a ligand exchange procedure can be carried out to yield aminated nanoparticles that are then cross-linked using epoxy chemistry. The result is a magnetic nanoparticle component that is covalently linked and well separated. By using this ‘matrix-free’ approach the nanocomposite possesses a substantially increased magnetic nanoparticle fraction, while still maintaining good separation, leading to a superparamagnetic nanocomposite with strong magnetic properties.

An ensemble of superparamagnetic nanoparticles will align their magnetic moments with an external applied magnetic field much like paramagnetic materials (which have low and linear susceptibility). However, the magnetic susceptibility of the ensemble of superparamagnetic nanoparticles is much larger and more like a ferromagnet (which have high and superlinear susceptibility). A large susceptibility is important for improving inductance and switching performance. Equally important, this new core material has the potential for high magnetic flux saturation (1.0 T) that is comparable to commonly used core materials including pure iron (2.15 T), SiFe alloy (1.87 T), and Metglas (1.60 T). This high saturation value allows for higher switching currents to be used, increasing the inductor power density.

By combining this new, high performance, magnetic core material with microelectromechanical systems (MEMS) technology, it becomes possible not only to miniaturize but also to integrate microinductors with transistors on the same wide band-gap semiconductor chip. This provides a significant technological leap forward towards the ultimate scaling of power converter technology to achieve a fully integrated, monolithic PSoC. See S. C. O. Mathuna et al., IEEE Trans. Power Electron. 20, 3 (2005); and C. Ó. Mathúna et al., IEEE Trans. Power Electron. 27, 11 (2012).

### Theory

Most inductors used for switched mode power converters are toroidal inductors. Such toroidal inductors use magnetic cores with a toroidal (circular ring or donut) shape, around which wire is wound. Toroidal inductors are widely utilized for power electronics as they have closed magnetic paths for higher power density and don't produce significant external fields resulting in electromagnetic interference (EMI) and losses in nearby conductors. MEMS toroidal inductors have been modeled and experimental results provided for embedded inductors with both silicon and air cores. See M. Araghchini and J. H. Lang, J. Phys.: Conf. Ser. 476, 1 (2013). Unfortunately, the lack of a magnetic power amplifying core limits the total inductance to 45 nH for these inductors. To first order, the inductance of a toroidal inductor with a rectangular cross section is given by the following equation:

$$L = \frac{{μ}_{eff} {μ}_{0} {N}^{2} h}{2 π} ln ( \frac{b}{a} ) , \qquad ( 1 )$$

where μ_{eff} is the effective permeability for gapped cores or simply the relative permeability for uncapped or distributed gap cores, μ₀ is the vacuum permeability, N is the number of wire turns, h is the core height or thickness, a is the inner radius, and b is the outer radius. This simple equation clearly shows how inductance increases when μ_{eff}, N, h, and the ratio of b/a increases. However, while providing a good, first approximation under DC conditions, this equation falls quite short when considering effects due to nonlinear core materials, core losses, uneven magnetic flux distribution in the core, distributed wiring capacitance, and resistive wiring losses due to skin depth, proximity, and other effects over frequency due to AC currents.

Magnetic losses are often expressed in power density per cycle with units of J/m³. In the case of hysteresis, the equation describing this is the following:

$$\frac{{P}_{h y s}}{V} = ∮ H ( t ) dB . \qquad ( 2 )$$

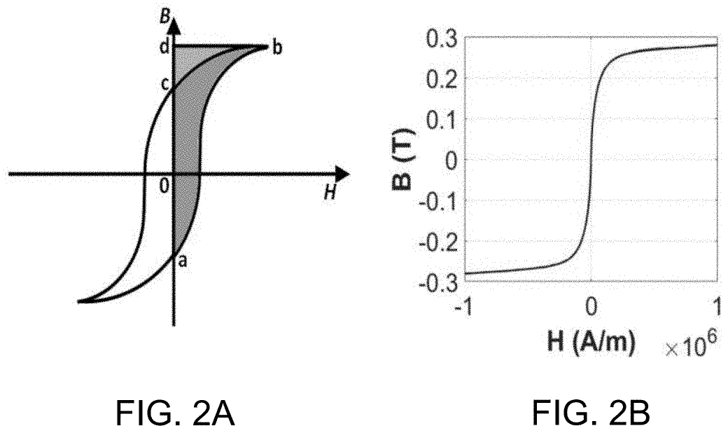

Thus, the power lost per unit volume of core material over one switching period is given by the area traced out by the points a, b and c shown in FIG. 2A. The nanocomposites can be designed so that the nanoparticles are always above their blocking temperature (i.e., the temperature at which single domain nanoparticles become superparamagnetic), resulting in no hysteresis and therefore zero loss, as shown in FIG. 2B.

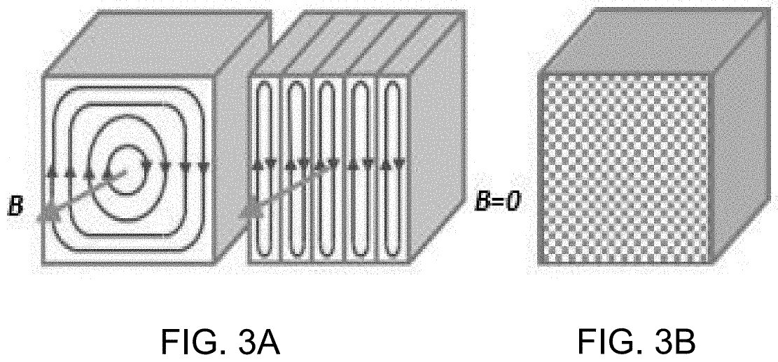

FIG. 3A illustrates the formation of eddy currents, which are internal loop currents that oppose a time-varying magnetic field and result in additional magnetic energy loss. Eddy current loss can be expressed by the following:

$$\frac{{P}_{eddy}}{V} = \frac{ω {B}^{2} A}{48 ρ} , \qquad ( 3 )$$

where A is the cross-sectional area of the core and ρ is the core resistivity. Laminated iron cores help to reduce this effect by shrinking the size of the loops. Nevertheless, eddy currents are still present and contribute to loss in laminated cores. Since the iron nanoparticles of the present invention are uniformly and spatially separated by a non-conducting epoxy molecule in the core material, the matrix is a dielectric that cannot support the formation of eddy currents and, thus, an opposing B-field, as shown in FIG. 3B. Furthermore, as the nanoparticles typically have diameters of 20 nm or less, they are too small to support substantial eddy currents.

Researchers have tried developing a magnetic core with a nanoparticle medium for on-chip planar RF inductors. See C. Yang et al., “On-chip RF inductors with magnetic nano particles medium,” 16th International Solid-State Sensors, Actuators and Microsystems Conference (2011), p. 2801. A prototype design was constructed using a nickel-iron permalloy (Ni₈₀Fe₁₇Mo₃) fill. This fill consisted of commercially obtained permalloy ferromagnetic particles crudely mixed into regular photoresist which was spin-coated or selectively filled around the planar inductor for a fully-closed magnetic path. An impressive 8 GHz frequency performance was achieved due to the low eddy current loss in the magnetically dispersed medium. Despite the low eddy current loss, this nanoparticle medium still possessed a significant hysteresis loop with coercivity, Hc, of 9.5 kA/m and a low 0.07 T magnetic flux saturation due most likely to its low packing fraction. Thus, only sub-nH inductance was achieved which may suffice for RF inductors but not for power inductors.

### Modeling

There are many ways to model inductors ranging from simple analytical models incorporated in commercial software, such as SPICE and MATLAB®, to more sophisticated finite element (FE) models, such as Ansoft Maxwell field simulator's magnetostatic solver and COMSOL Multiphysics®. Each has their strengths and weaknesses depending on aspects such as the breadth of physics involved, type of core material used (air, linear, nonlinear), and geometrical complexity to the more practical, but still important, licensing costs. COMSOL Multiphysics 5.3 allows the user to customize material properties, model complex geometries representative of realistic microfabricated features, and perform parametric sweeps of inductor geometry, number of turns, core material properties, etc., to explore the vast design space to obtain a specific, optimized inductance. COMSOL is also capable of multidomain simulation (i.e., static, frequency, and time domain), exploring temperature effects from Joule heating and leakage flux, and, finally, incorporating additional physics via customized equations if necessary. In particular, COMSOL Multiphysics can model effects due to nonlinear core materials, core losses, uneven magnetic flux distribution in the core, distributed wiring capacitance, and resistive wiring losses due to skin depth, proximity, and other effects over frequency due to AC currents. Therefore, COMSOL Multiphysics was chosen to model the microinductors. See J. D. M. Mickey et al., Design Optimization of Printed Circuit Board Embedded Inductors through Genetic Algorithms with Verification by COMSOL [online]. 2013 [retrieved on 17 Apr. 2018]. Retrieved from the Internet: <URL: https://www.comsol.com/paper/download/181351/madsen paper.edf>; T. A. H. Schneider et al., Optimizing Inductor Winding Geometry for Lowest DC-Resistance using LiveLink between COMSOL and MATLAB [online]. 2013 [retrieved on 17 Apr. 2018]. Retrieved from the Internet: <URL: https://www.comsol.com/paper/download/181441/schneider paper.pdf (accessed); COMSOL, Inductance of a Power Inductor [online]. 2017 [retrieved on 17 Apr. 2018]. Retrieved from the Internet: <URL: https://www.corsol.com/model/inductance-of-a-power-inductor-1250>; A. Pokryvailo, Calculation of Inductance of Sparsely Wound Toroidal Coils [online]. 2016 [retrieved on 17 Apr. 2018]. Retrieved from the Internet: <URL: https://www.comsol.corn/paper/download/362301/pokryvailo paper.pdf>; and COMSOL, Modeling a Spiral Inductor Coil [online]. 2017 [retrieved on 17 Apr. 2018]. Retrieved from the Internet: <URL: https://www.comsol.com/model/modeling-a-spiral-inductor-coil-21271>.

As an example of the invention, two different microinductors, a 500 nH input inductor and a 2 μH output inductor, were modeled as part of a switched mode buck converter circuit. Both inductors need to handle a switching frequency of 1 MHz. Preferably, the output inductor also would have an average power handling capacity of 8 W with a power density of greater than 100 W/in³. Since parametric equations were used to model the geometry, the same model can be used to model both microinductor designs simply by changing the input parameters for each one. A rough design space was mapped out for both 500 nH and 2 μH microinductors using the analytical expression given in Eq. (1). Fabrication constraints were placed on things such as wire and nanocomposite core thickness while trying to make the overall form factor as small as possible.

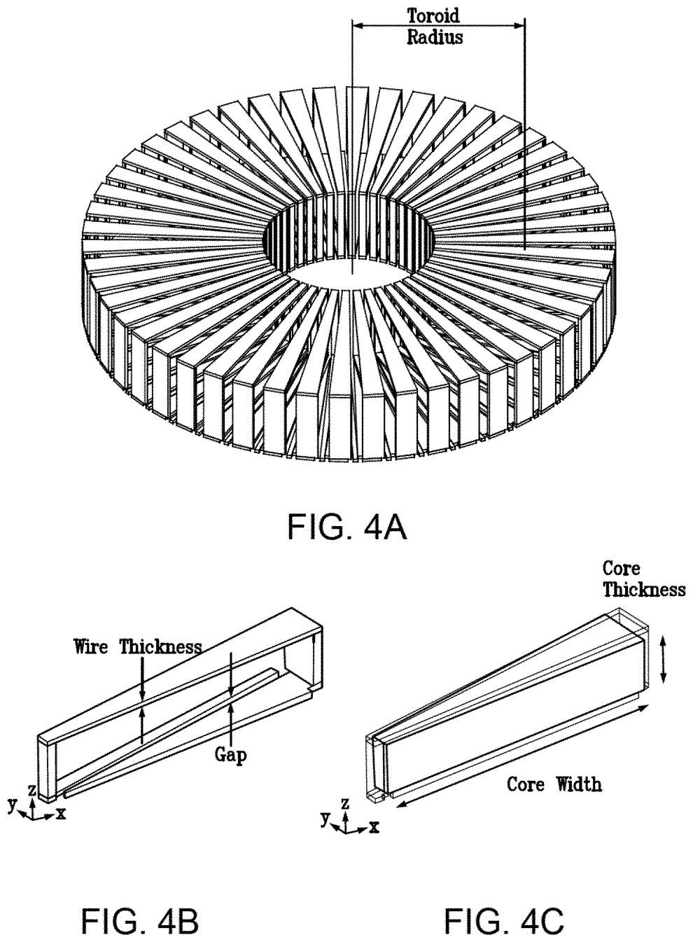

Only one single turn of the inductor, both copper coil and core segment, was used as a unit cell and periodic boundary conditions employed to model an entire toroid, as shown in FIG. 4A. Exploiting this cylindrical symmetry reduces the size of the model by the number of windings, greatly reducing the problem size and, thus, the computational requirements. The geometry of both the single, copper wire turn and the core segment were parameterized so that both could be easily changed and parametric sweeps performed to optimize the microinductor form factor. Unfortunately, due to the use of the Coil Geometry Analysis step in COMSOL that computes the path of the wires in complex coils with non-constant cross section, this prohibits the use of built in optimization studies that might have made this analysis even easier. FIGS. 4B and 4C display CAD renderings of single turn copper wire and single turn core geometries, respectively. As shown in FIG. 4B, the top and bottom wiring layers comprise triangular-shaped elements wherein the inner vertices are offset slightly to enable the triangular elements of the top and bottom layers to be connected in series, providing a single coil loop. For the numerical simulation, these shapes can be made using rectangles, curves, and Bézier polygons with parametric equations that enable the modeler to adjust simply by inputting different values for the parameters listed in Table 1. The choice behind using these shapes to build this rather complex single wire turn instead of using a much simpler spiral current was based on three reasons: 1) it captures the effects of resistive wiring losses due to skin depth and proximity effects and can be programmed to capture Self Resonance Frequency (SRF) due to distributed wiring capacitance, 2) it captures effects related to real geometries produced using microfabrication and other additive manufacturing processes, and 3) it can be used to automatically generate designs of optimized inductors for creating photomasks or 3D printing input files without having to redraw these structures again in separate CAD software.

While the number of wire turns at both the inner radius and the outer radius must be constant, parametric design and microfabrication allows the designer to vary the size and shape of the wire turns to enable more flexibility when it comes to varying the number of turns as well as the outer/inner microinductor radius, b/a. Increasing both can help boost the inductance value, while keeping the overall microinductor size small. Additional benefits include lithographically defining finite gap spacings between turns that minimizes this gap while increasing the overall degree of wire coverage of the microinductor core. Sullivan has shown that stray magnetic fields in the region containing the gaps lead to current crowding at the edges of the windings facing the gaps, affecting the overall AC resistance. See C. R. Sullivan et al., “Design and Fabrication of Low-Loss Toroidal Air-Core Inductors,” IEEE Power Electronics Specialists Conference, p. 1754 (2007). This is a consequence of AC current flowing in a skin-depth on the inner surface of a coil winding. Having a minimal slit width or gap between coil turns helps to reduce the AC resistance. Another high frequency consequence due to this skin effect involves the benefits of flat conductors versus round conductors. A flat conductor surface such as that achieved by Phinney will have less current crowding than the ridged surface of a wire-wound toroid. See J. Phinney et al., “Multi-resonant microfabricated inductors and transformers,” IEEE 35th Annual Power Electronics Specialists Conference, p. 4527 (2004). Flat coil turns defined by lithography with minimal gap spacing between turns helps achieve a minimum AC resistance for a given size and number of turns by making maximal use of that surface, as shown in FIG. 4B.

For materials properties, bulk copper wire was used for modeling the coil windings. The important parameter for the winding is the conductivity, which is 6.0×10⁷ S/m for bulk copper. For the superparamagnetic iron nanocomposite, a first generation, non-optimized formulation was used for the model. Material conductivity was measured using a four-point probe setup and a Keithley 2400 SourceMeter on a 0.75″ long by 0.25″ wide molded epoxy sample. All four probes were spaced 0.125″ apart with the SourceMeter sourcing current through the outer two probes while measuring the voltage drop between the inner two probes. As expected, the material was highly resistive and a calculated value of ˜1 μS/m was obtained for the material conductivity.

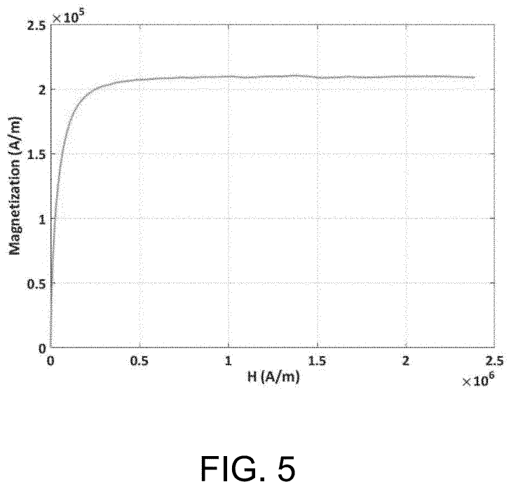

FIG. 5 is a plot of the MH data taken using a Quantum Designs Versalab Vibrating Sample Magnetometer (VSM) of the first-generation superparamagnetic iron nanocomposite. This data plot was converted to a BH curve and then inverted to an HB curve for the Magnetic Fields (m) interface used for this model. This curve provides the magnetic field inputs for the nanocomposite from which the model can generate H and μ_{eff} for an input value of magnetic flux, B.

### Physics Interfaces

The single physics interface used in this model was the Magnetic Fields (mf) interface. The governing equations, initial conditions and boundary conditions used are stated below.

Magnetic Fields (mf):

∇×H=J, (4)

B=∇×A, (5)

J=σE, (6)

where H is the magnetic field, J is the current density, B is the magnetic flux density, A is the magnetic vector potential, and σ is the electrical conductivity. Automatic values of A=(0, 0, 0) were applied for initial background flux conditions and a magnetic insulation condition, n×A=0, was applied to the outer boundary of the spherical air volume applied but not shown in the previous images.

$$H = f ( \vert B \vert ) ( \frac{B}{\vert B \vert} ) \qquad ( 7 )$$

Eq. (7) illustrates how the model calculates the magnetic field, H, from the HB curve given a magnetic flux, B, from an applied current density, J.

B=μ₀μᵣH (8)

Eq. (8) is used to determine the relative permeability, μᵣ, of the nanocomposite material from the applied current density once H and B are known from Eq. (7).

(jωσ−ω²ε₀)A+∇×(μ₀⁻¹×A−M)−σv×(∇×A)=Jₑ (9)

Finally, the full governing subset of Maxwell's equations for the frequency domain is shown in Eq. (9) where ω is the angular frequency, ϵ₀ is the vacuum permittivity, M is the magnetization, v is the velocity of the conductor, and Jₑ is an externally generated current density. See COMSOL, COMSOL Multiphysics Reference Manual 5.3, (2017). Again, COMSOL takes care of the core magnetization via the HB curve and the external generated current density via the current input by the modeler. At this point, all the necessary variables for solving Maxwell's equations are satisfied.

A special coil domain setting is applied to the shapes comprising the single coil turn. In this setting, a current is applied consisting of a 1 A DC component with a 10-mA harmonic perturbation (AC) component. This enables a frequency sweep using a Frequency-Domain Perturbation study step.

### Meshing

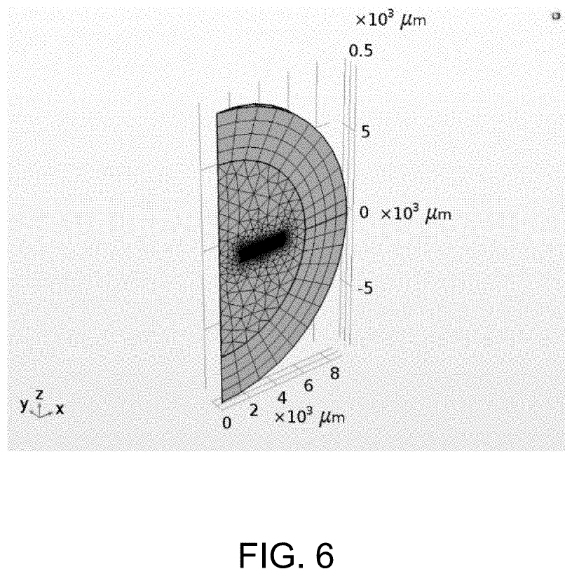

As mentioned previously, cylindrical symmetry was exploited to reduce the number of nodes. Thus, only a single coil turn with its associated core segment was meshed. An air volume with Infinite Element domains on the exterior was used to approximate a very large distance from the region of interest. This helps to increase both the accuracy of the model as well as calculate the extent of the external poloidal field outside the coils that is ever present in toroidal inductors but seldom mentioned as it tends to be far less than the toroidal field inside the coils. The generated mesh is shown in FIG. 6. A user-controlled mesh was applied to the model. Free tetrahedrals with a size set to “Extra fine” were applied to the copper wire shapes and the nanocomposite core segment while free tetrahedrals with a size set to “Finer” were applied to the surrounding air volume. A swept mesh was applied to the remaining Infinite Element domains. This configuration gives an average mesh quality of approximately 0.6.

### Study

Three different study steps were used to model the microinductor. A Coil Geometry Analysis was used for Step 1. This study step solves an eigenvalue problem for the current flow in a Multi-Turn Coil Domain node that gives the current density produced by a bundle of conductive wires. A Stationary study was used for Step 2. This step solves the stationary Partial Differential Equation (PDE) for the DC solution making it easier for the AC solution in the subsequent Frequency-Domain Perturbation study to reach convergence. For Step 3, a Frequency-Domain Perturbation study was used as the regular Frequency Domain could not seem to handle the nonsymmetrical matrices involved. This study step is used to solve for studies of small harmonic oscillations about a bias solution by computing a perturbed solution of the linearized problem around the linearization point (or bias point) computed in the first Stationary study step. As mentioned previously, a 1 A DC current is applied for computing the Stationary study while a 10-mA harmonic perturbation (AC) component is used computing the Frequency-Domain Perturbation study.

### Simulation Results

Table 1 lists the various parameters used to model both a 2 μH and a 500 nH microinductor for a next generation, high performance, power converter to operate at 1 MHz switching speeds.

TABLE 1
2 μH and 500 nH microinductor geometrical parameters and values.
2 μH/500 nH Microinductor Geometry

| | Parameter | | | |
|---|---|---|---|---|
| | 2 pH Value | | 500 nH Value | |
| Gap | 50 | μm | 50 | μm |
| Toroid Radius | 3 | mm | 3 | mm |
| Core Thickness | 0.5 | mm | 0.4 | mm |
| Core Width | 2.9 | mm | 0.9 | mm |
| Wire Thickness | 50 | μm | 50 | μm |

| | | |
|---|---|---|
| Number of Turns, N | 50 | 50 |

Both inductors have the same 3 mm toroid radius, 50 μm wire thickness, 50 turns, and 50 μm wire-to-wire gap spacing. However, the 2 μH microinductor core is slightly thicker at 0.5 mm as compared to the 0.4 mm thick core of the 500 nH microinductor. The core width is also larger at 2.9 mm for the 2 μH versus 0.9 mm for the 500 nH microinductor.

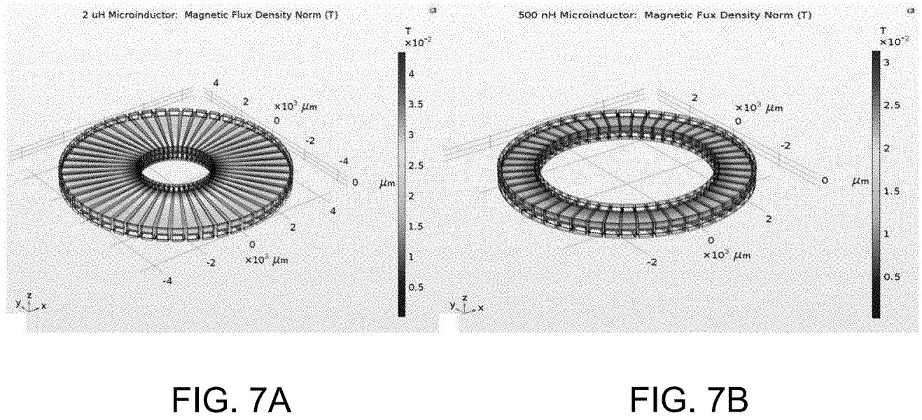

FIGS. 7A and 7B show magnetic flux density normal plots for the 2 μH and 500 nH microinductors, respectively. A slice through the center of the z-plane is shown with low to high normal flux density indicated by color ranging from blue (low) to red (high). As expected, the highest magnetic flux density of 0.04 mT in the core can be seen as an annular region closest to the inner radius of the 2 μH microinductor. This region experiences the highest current density due to the both the density of wire turns at the inner radius as well as the narrowing of the wire turns themselves as they go from the outer toroid radius to the inner toroid radius. A maximum normal flux density of 0.03 mT can be seen at the inner region of the 500 nH microinductor. The 500 nH microinductor exhibits a more uniform flux distribution than the 2 μH microinductor due to the higher aspect ratio, thus, making more efficient use of the nanocomposite core material. Both inductors, however, have outer diameters of less than 1 cm. Thus, both microinductors can be considered “chip scale” from the standpoint of their overall form factor and what is considered a reasonable chip size.

TABLE 2
Modeled electrical parameters for 2 pH and 500 nH
microinductors at 1 MHz.
1 MHz microinductor modeled electrica parameters

| | AC | | | Average | Power |
|---|---|---|---|---|---|
| | resistance | | Reactance | output power | density |
| Inductance | (Ω) | Q | (Ω) | (W) | (kW/in³) |
| 2 μH | 0.41 | 27 | 13 | 7 | 3.9 |
| 500 nH | 0.13 | 27 | 3 | 2 | 3.8 |

Table 2 provides some of the electrical parameters of interest for the two microinductors. The AC resistance at 1 MHz is on par with that of similar MEMS air core inductors of around 0.4Ω, but with higher values for quality factor, Q, of around 27. See M. Araghchini, (MEMS) Toroidal Magnetics for Integrated Power Electronics, PhD Thesis, Massachusetts Institute of Technology, (2013). This is to be expected as the core helps to boost the stored energy, whereas many air core inductors tend to suffer from low values of Q. The average output power for the 2 μH output microinductor is around 7 W with the first-generation superparamagnetic iron nanocomposite core material. The power density according to the model for the 2 μH microinductors is 3.9 kW/in³. This also is not surprising, as magnetic devices based on currents tend to scale very well with miniaturization.

To further improve the model, several more features can be added to capture physics that play an important role, particularly at high frequencies. As mentioned earlier, zero hysteresis and eddy current loss are important features of this superparamagnetic nanocomposite over commercial ferrite materials in use today. However, other loss mechanisms can affect microinductor performance. To account for these loss mechanisms, measurements over frequency can be made using a BH analyzer with each successive improvement in formulation. COMSOL handles magnetic losses using complex permeabilities:

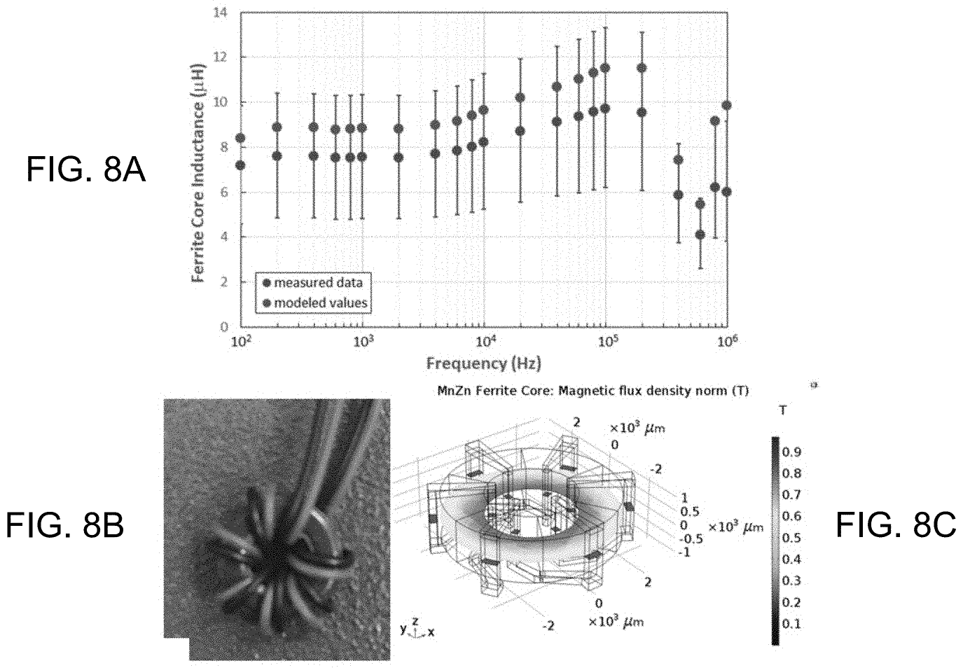

B=μ₀(μ′−iμ″)H (10)

where μ′ is the real part of the relative permeability, μᵣ and μ″ is the imaginary part of the relative permeability that represents loss in the system. Benchmarking was used to validate the model using a commercial MnZn ferrite toroidal core, Ferroxcube TC5.8/3.1/1/5-3B7. This core has a 6-mm outer diameter, a 3-mm inner diameter, and a height of 1.52 mm. 6 wire turns were used to measure values for μ′, μ″, and L on an Iwatsu B-H analyzer SY-8219. The measured values of μ′, μ″, were inserted into the COMSOL model and used to model L. FIG. 8A provides a comparison between measured values of L using the BH analyzer and modeled values of L generated by the COMSOL model. The measured data and the modeled values for the ferrite core are close to one another with a point-to-point difference between 1.2 and 3.8 μH across the range of frequencies evaluated. The difference between the model and the measurement can be accounted for by the various uncertainties in the measurement. First, there is a manufacturing tolerance of ±0.18 mm in both the inner and outer core diameters as well as the thickness of the core. Secondly, upon inspection of the coil windings themselves, it appeared there were substantial air gaps between the wire windings and the ferrite core itself that were estimated to average around 0.3 mm. These gaps are a result of how small the ferrite core was and how difficult it was to keep the windings flush with the surface of the core. The model was run again with this additional average air gap and found to cause a reduction in inductance, particularly at higher frequencies, presumably due to flux leakage. This error was assigned to the relative permeability, μ′, and ranged from 64 at 100 Hz to 328 at 1 MHz. Since μ′ can only get worse due to flux leakage, a skewed error distribution occurs with positive error bars being greater than negative ones. This leads to positive errors in inductance ranging from 2.6 μH to 3.2 μH from 100 Hz to 1 MHz and negative errors ranging from 2.6 μH to 2.2 μH from 100 Hz to 1 MHz. For this case, the modeled values of inductance fall within the margin of error for most of the range. With more precise core and coil dimensions and more numbers of turns afforded by microfabrication, one can assume that a better match will occur between modeling and measurement.

Another feature the current model lacks is a means of calculating the distributed capacitance in the coil windings themselves. This is necessary to calculate the self-resonant frequency (SRF) to determine the operational bandwidth of the microinductors. While this is not automatically included by COMSOL to model coils, incorporating this physics via customized equations is an advantage COMSOL has to perform this calculation. Analytical expressions for this have been used by Sullivan. See C. R. Sullivan et al., “Design and fabrication of low-loss toroidal air-core inductors,” IEEE Power Electronics Specialists Conference (IEEE, Orlando, Fla., 2007), p. 1754.

The model described above addresses only the electromagnetic physics underlying these microinductors. Energy losses due to flux leakage to the underlying substrate and surrounding circuit elements as well as Joule heating losses is also possible by means of COMSOL's thermomechanical (TM) multiphysics.

Finally, significant improvements in modeled microinductor designs can be made through improvements in the magnetic performance of the iron nanocomposite material itself. At 1 A applied current, μᵣ is around 8 for a material where J_{S} is only 0.25 T. Both parameters can be improved in subsequent generations of iron nanocomposites. These improvements will enable shrinking the size of the device even further as well as reducing the number of wire turns needed for a given value of inductance. This will have a cascade effect in terms of reducing coil resistance, both DC and AC, improving both copper loss as well as the Q value. It will also help improve both average output power as well as power density performance over frequency.

### Fabrication of the Microinductor

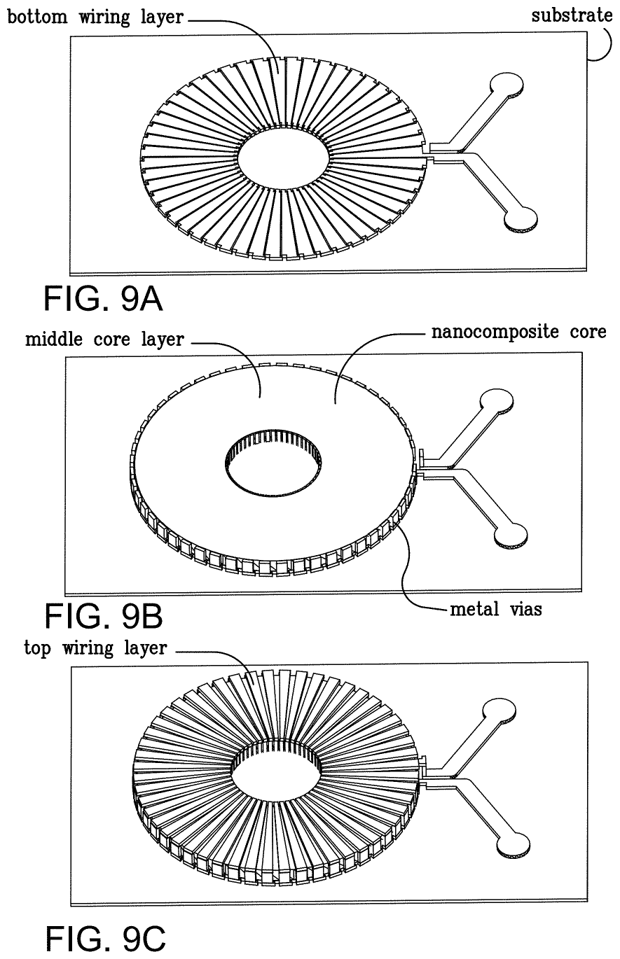

The toroidal microinductor comprises a planar coil design with a nanocomposite core material in between the lower and upper halves of the planar coil. The microinductor can be fabricated using a 3-layer process employing micromachining or 3D printing techniques, as shown in FIGS. 9A-9C. The fabrication process starts with a substrate and grows the microinductor layer by layer. The starting substrate can comprise an insulating material, such as a thermally grown silicon nitride layer on silicon, sapphire, glass, or plastic.

As shown in FIG. 9A, the bottom wiring layer comprises a microns-thick (e.g., 1 μm to 100 μm) layer of copper, gold, silver, or other highly conductive metal can then be patterned on the substrate. As an example, the bottom wiring layer can be patterned using the following microfabrication steps:
a. Patterned lift-off of a Ti/Cu/Ti, Cr/Cu/Cr, Ti/Au/Ti, or Cr/Au/Cr metallic seed layer. For example, the patterned seed layer can comprise 25 nm Cr/75 nm Cu/25 nm Cr.
b. Spin coat and photo pattern high aspect ratio SUEX® or some other epoxy photoresist mold and cure for permanent placement to provide an infilled, insulated gap between the seed layer pattern. For example, a 50 μm thick patterned SUEX layer can hard baked at 200° C. for 30-60 minutes to provide a permanent insulating film.
c. Quick hydrofluoric acid or chrome etch dip to remove top seed layer (e.g., 25 nm Cr) to reveal a fresh copper seed surface.
d. Electroplate copper, gold or some other highly conductive metal up to the surface of the SUEX® or other epoxy photoresist mold. For example, 50 μm-thick copper can be electroplated on the fresh copper seed surface.

As shown in FIG. 9B, the middle core layer is comprised of high-aspect-ratio (10:1) metal vias plus a superparamagnetic nanocomposite disk-like core. As an example, a fabrication method produces a 3D mold with metallized vias for electrically connecting the bottom and top wiring layers and a toroidal shaped cavity for forming an iron/iron oxide nanocomposite core. The 3D printed mold can be fabricated by a printing tool, such as the Photonic Professional GT built by Nanoscribe. This method can create a mold comprising a set of hollow pore molds for electroforming the copper vias and a toroidal shaped cavity for forming the iron/iron oxide nanocomposite core. The fabrication steps for this method are:
a. Direct-write 3D printed mold on top of bottom wiring layer to a total height of 500 μm for the exemplary microinductors.
b. O₂ plasma clean to remove resin residue at the bottoms of via pores.
c. Electroplate copper, gold, or other highly conductive metal up to the top surface of the 3D printed mold via pores. For example, 500 μm copper can be electroplated in the via pores.
d. Deposit iron/iron oxide nanocomposite into toroidal shaped cavity up to the top surface of the 3D printed mold and cure. The top surface of the deposit can be planarized to expose the copper vias.
   Alternatively, a solid disk of nanocomposite core material can be deposited or molded on top of the bottom wiring layer with an outer diameter that extends beyond the outer toroid radius. Circumferential via holes can then be laser drilled through the disk at the inner and outer toroid radii and backfilled with copper (e.g., via electroplating) to connect that coil turns in the top and bottom wiring layers.

As shown in FIG. 9C, the top wiring layer comprises a microns-thick (1 μm to 100 μm) patterned layer of copper, gold, silver, or other highly conductive metal. As an example, the top wiring layer can be patterned using the following fabrication steps:
a. Patterned lift-off of a Ti/Cu/Ti, Cr/Cu/Cr, Ti/Au/Ti, or Cr/Au/Cr metallic seed layer. For example, the patterned seed layer can comprise 25 nm Ti/75 nm Cu/25 nm Ti.
b. Spin coat and photo pattern high aspect ratio SUEX® or some other epoxy photoresist mold. For example, a 50 μm thick patterned SUEX layer can hard baked at 200° C. for 30-60 minutes to provide a permanent insulating film, or soft baked at 125° C. for 60 minutes to provide a removable film.
c. Quick hydrofluoric acid or chrome etch or sulfuric acid dip to remove top metal film layer (e.g., 25 nm Ti) to reveal fresh copper surface.
d. Electroplate copper, gold or some other highly conductive metal up to the surface of the SUEX® or some other epoxy photoresist mold. For example, 50 μm-thick copper can be electroplated on the fresh copper seed surface.
e. Photoresist mold can be removed or cured and left permanently in place depending on trade-offs amongst time, cost, etc.

Other methods can be used to fabricate the microinductor. For example, an additive manufacturing method, such as a high-resolution 3D metal printer, can be used to directly write the layers. To fabricate a toroidal microinductor using an additive manufacturing process, a multi-layer print can be designed with two conductive layers of metal ink separated by a core of magnetic material. The bottom wiring layer can be made by printing the separate conductive triangular elements in a circle (toroid). For example, the bottom wiring layer can be made by printing silver triangular elements that can then be cured at 170° C. on a hot plate for 30 minutes. The middle core layer can comprise the nanocomposite core material that can be cast or printed on the bottom wiring layer. The core can have a trapezoidal cross-section with slanted inner and outer diameter sidewalls to enable printing of conductive connections between the triangular elements of the top and bottom layers. Finally, the top wiring layer can be written directly on the middle core layer, for example using silver ink. This layer can be cured with the same parameters as bottom wiring layer.

The present invention has been described as a toroidal microinductor comprising a nanocomposite magnetic core. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A toroidal microinductor, comprising
a nanocomposite magnetic core comprising superparamagnetic nanoparticles and having a toroidal shape; and
one or more coil turns surrounding the nanoparticle magnetic core.

2. The toroidal microinductor of claim 1, wherein the superparamagnetic nanoparticles comprise iron, cobalt, nickel, or alloys or compounds thereof.

3. The toroidal microinductor of claim 1, wherein the superparamagnetic nanoparticles comprise Fe/FeₓO_{y} core-shell nanoparticles.

4. The toroidal microinductor of claim 1, wherein the superparamagnetic nanoparticles comprise Fe₃O₄ nanoparticles.

5. The toroidal microinductor of claim 1, wherein the superparamagnetic nanoparticles are less than 100 nm in diameter.

6. The toroidal microinductor of claim 5, wherein the superparamagnetic nanoparticles are less than 20 nm in diameter.

7. The toroidal microinductor of claim 1, wherein the superparamagnetic nanoparticles are suspended in a polymer matrix.

8. The toroidal microinductor of claim 1, wherein the superparamagnetic nanoparticles are covalently cross-linked in an epoxy network.

9. The toroidal microinductor of claim 1, wherein the toroidal microinductor has a toroid outer diameter of less than 1 cm.

10. The toroidal microinductor of claim 1, wherein the toroidal microinductor has a height of less than 1 mm.

11. The toroidal microinductor of claim 1, wherein the toroidal microinductor has a form factor of less than 1 cm³.

12. The toroidal microinductor of claim 1, wherein the toroidal microinductor has an inductance greater than 1 nH.

13. The toroidal microinductor of claim 1, wherein the toroidal microinductor has a power density of greater than 3 kW/in³.

14. The toroidal microinductor of claim 1, wherein the toroidal microinductor has an AC resistance of less than 1 ohm at 1 MHz.

15. The toroidal microinductor of claim 1, wherein the toroidal microinductor has a quality factor greater than 25 at 1 MHz.

16. The toroidal microinductor of claim 1, wherein the toroidal microinductor is microfabricated using MEMS technologies.

17. The toroidal microinductor of claim 1, wherein the one or more coil turns comprises flat coil turns.
